(19) United States
(12) Patent Application Publication
(10) Pub. No.: US 2026/0096425 A1
(43) Pub. Date: Apr. 2, 2026

(54) METHOD FOR FABRICATING MASKLESS DENDRITIC SILICON NANOSTRUCTURE ARRAY AND SILICON WAFER PREPARED THEREBY

(71) Applicant: Guangdong University of Technology, Guangzhou (CN)

(72) Inventors: Guanghan HUANG, Guangzhou (CN); Jiantao LIU, Guangzhou (CN); Wenjie MIAO, Guangzhou (CN); Jiawei LIAO, Guangzhou (CN); Shuang LIU, Guangzhou (CN); Chengqiang CUI, Guangzhou (CN); Yu ZHANG, Guangzhou (CN); Guannan YANG, Guangzhou (CN)

(21) Appl. No.: 19/413,205

(22) Filed: Dec. 9, 2025

(30) Foreign Application Priority Data
Mar. 14, 2025 (CN) 202510303767.X

(51) Int. Cl. H10W 40/00; C23C 14/18; C23C 14/58; H10W 40/22

(52) U.S. Cl. CPC H10W 40/03; C23C 14/185; C23C 14/5846; C23C 14/5873; H10W 40/22

(57) ABSTRACT

A method for fabricating a maskless dendritic silicon nanostructure array, in which a copper layer is deposited on a surface of a silicon substrate, and passivated to form an insulating passivation film; a first laser induction is performed using a first laser beam to remove the insulating passivation film from a designated region and form a primary needle-shaped protrusion structure; a second laser induction is performed on the primary needle-shaped protrusion structure using a second laser beam to form a secondary dome-shaped protrusion structure, thereby forming a dual-level needle-shaped seed layer; the dual-level needle-shaped seed layer is subjected to parameter-controlled electrodeposition to grow dendritic microstructures, so as to obtain a silicon wafer containing the maskless dendritic silicon nanostructure array. A silicon wafer with a silicon nanostructure array fabricated by such process is also provided.

### CROSS-REFERENCE TO RELATED APPLICATIONS

This application claims the benefit of priority from Chinese Patent Application No. 202510303767.X, filed on Mar. 14, 2025. The content of the aforementioned application, including any intervening amendments made thereto, is incorporated herein by reference in its entirety.

### TECHNICAL FIELD

This application relates to the fabrication of silicon surface microstructures, and more particularly to a method for fabricating a maskless dendritic silicon nanostructure array and a silicon wafer prepared thereby.

### BACKGROUND

As the power and integration level of electronic devices continue to rise, the heat dissipation has become a critical bottleneck limiting the performance and reliability of high-heat-flux devices. In the prior art, enhanced cooling technologies based on microchannels have emerged as a key solution due to their efficient heat and mass transfer capabilities. Moreover, by constructing bionic micro/nano-structures on the interior surfaces of microchannels to regulate the interfacial thermodynamic behavior, the capillary wetting capacity and evaporation heat transfer coefficient of the microchannels can be significantly enhanced, thereby improving the overall thermal management performance of the system.

Currently, conventional fabrication methods for interfacial enhancement micro/nano-structures within microchannels includes etching, sintering, laser processing and electrical discharge machining. These techniques offer advantages of relatively low cost and high efficiency, but they also struggle with several notable drawbacks.

(1) These conventional methods typically produce randomly distributed structures such as nanowires, nano blades, nanospheres, nanopillars or nanopores. Such randomness results in an irregular distribution of nanostructures inside the microchannels, making it impossible to achieve the optimal overall thermal conductivity.

(2) The random distribution of nanostructures leads to nondirectional liquid transport, failing to effectively address localized hotspot issues in chips.

(3) Under high heat flux conditions, the micro/nanostructures on the inner surface of the microchannels require an extremely high specific surface area to enhance the surface heat transfer coefficient, whereas single-level microstructures fabricated by conventional methods cannot meet this requirement.

(4) The conventional patterned structure fabrication methods often rely on a mask, which increases the fabrication cost and reduces the production efficiency.

### SUMMARY

An object of the disclosure is to provide a method for fabricating a maskless dendritic silicon nanostructure array to overcome the following problem in the prior art: (1) the nanostructures fabricated by the conventional methods often have an irregular distribution, resulting in poor thermal conductivity; and (2) the single-level microstructure fabricated by traditional methods fails to offer a sufficient specific surface area to meet the current heat transfer coefficient requirements. The present disclosure also provides a silicon wafer with the maskless dendritic silicon nanostructure array prepared by such method, so as to solve the problem of localized hotspots in the existing chips caused by the random distribution of surface nanostructures.

Technical solutions of the present disclosure are described as follows.

In a first aspect, this application provides a method for fabricating a maskless dendritic silicon nanostructure array, comprising:
depositing a copper layer on a surface of a silicon substrate, and passivating the copper layer to form an insulating passivation film;
applying a first laser beam to a surface of the insulating passivation film for a first laser induction to remove the insulating passivation film from a designated region and form a primary needle-shaped protrusion structure within the designated region;
applying a second laser beam to a surface of the primary needle-shaped protrusion structure for a second laser induction to form a secondary dome-shaped protrusion structure, such that a dual-level needle-shaped seed layer is formed on the surface of the silicon substrate; and
subjecting the dual-level needle-shaped seed layer to parameter-controlled electrodeposition to grow dendritic microstructures on the dual-level needle-shaped seed layer, so as to obtain a silicon wafer containing the maskless dendritic silicon nanostructure array.

In some embodiments, the first laser induction and the second laser induction are performed using an ultraviolet femtosecond laser direct-writing device.

In some embodiments, the first laser beam has a pulse width of 80-100 fs and a wavelength of 300-400 nm.

In some embodiments, the second laser beam has a pulse width of 25-60 fs and a wavelength of 175-275 nm.

In some embodiments, the primary needle-shaped protrusion structure has a height of 2-6 μm, and the secondary dome-shaped protrusion structure has a size of 200-600 nm.

In some embodiments, an initial current density and a deposition time of the parameter-controlled electrodeposition satisfy the following function:

$$f ( t ) = Kt + b ;$$

wherein f(t) represents a real-time current density; K represents a current slope, and is 0.003-0.2 A/(cm²·s); t represents the deposition time, and is 30-200 s; and b represents the initial current density, and is 0.06-0.2 A/cm².

In some embodiments, an electrolyte solution used in the parameter-controlled electrodeposition is prepared by mixing a CuSO₄ solution having a concentration of 0.4-0.8 M with a H₂SO₄ solution having a concentration of 0.5-0.9 M.

In some embodiments, the copper layer is deposited on the surface of the silicon substrate by magnetron sputtering with pure copper as a target material; and the copper layer has a thickness of 5-7 μm.

In some embodiments, a thickness of the insulating passivation film is 0.5-2 μm.

In a second aspect, this application provides a silicon wafer, comprising:
a silicon nanostructure array;
wherein the silicon nanostructure array is obtained by the method described above.

Compared to the prior art, the present disclosure has the following beneficial effects.

Regarding the silicon wafer fabricated by the aforementioned method, microchannels are formed between dendritic silicon nanostructure units, allowing efficient capillary mass transfer along the microchannel walls. At the same time, since each dendritic silicon nanostructure unit includes multiple secondary dome-shaped protrusion structures and dendritic microstructures, a larger specific surface area is offered, which enables the efficient evaporative heat transfer along a direction perpendicular to the microchannels, thereby enhancing the heat transfer limit.

### BRIEF DESCRIPTION OF THE DRAWINGS

FIG. 1 schematically shows a pretreatment step in the fabrication method according to an embodiment of the present disclosure;

FIG. 2 schematically shows a second laser induction step in the fabrication method according to an embodiment of the present disclosure;

FIG. 3 schematically shows an electrodeposition step in the fabrication method according to an embodiment of the present disclosure;

FIGS. 4a-4b are scanning electron microscopy (SEM) images of a silicon wafer containing a maskless dendritic silicon nanostructure array obtained in Example 1 of the present disclosure, where FIG. 4b is an enlarged view of the portion marked by dashed box in FIG. 4a;

FIGS. 5a-5b are SEM images of a silicon wafer containing a maskless dendritic silicon nanostructure array obtained in Example 2 of the present disclosure, where FIG. 5b is an enlarged view of the portion marked by dashed box in FIG. 5a;

FIGS. 6a-6b are SEM images of a silicon wafer containing a maskless dendritic silicon nanostructure array obtained in a blank control group, where FIG. 6b is an enlarged view of the portion marked by dashed box in FIG. 6a;

FIGS. 7a-7b are SEM images of a silicon wafer containing a maskless dendritic silicon nanostructure array obtained in Example 3 of the present disclosure, where FIG. 7b is an enlarged view of the portion marked by dashed box in FIG. 7a;

FIGS. 8a-8b are SEM images of a silicon wafer containing a maskless dendritic silicon nanostructure array obtained in Example 4 of the present disclosure, where FIG. 8b is an enlarged view of the portion marked by dashed box in FIG. 8a; and

FIGS. 9a-9b are SEM images of a silicon wafer containing a maskless dendritic silicon nanostructure array obtained in Example 5 of the present disclosure, where FIG. 9b is an enlarged view of the portion marked by dashed box in FIG. 9a.

In the figures: 1—silicon substrate; 2—copper layer; 3—insulating passivation film; 4—second laser beam; 5—primary needle-shaped protrusion structure; and 6—secondary dome-shaped protrusion structure.

### DETAILED DESCRIPTION OF EMBODIMENTS

In order to make the objects, technical solutions and advantages of the present disclosure clearer, the present disclosure will be described clearly and completely below in conjunction with the accompanying drawings and embodiments. Obviously, described herein are merely some embodiments of the present disclosure, rather than all embodiments. Based on the embodiments in the present disclosure, all other embodiments obtained by those of ordinary skill in the art without making creative effort shall fall within the scope of the present disclosure defined by the appended claims.

For embodiments in which specific techniques or conditions are not explicitly indicated, the techniques or conditions described in the prior art or in product manuals may be employed. Any reagents or instruments for which the manufacturer is not specified are conventional products that can be obtained commercially.

Unless otherwise defined, all technical and scientific terms used in the present disclosure have the same meaning as commonly understood by those of ordinary skill in the art. The terms used herein are merely descriptive, and are not intended to limit the disclosure. As used herein, the term “and/or” refers to any and all combinations of one or more of the listed items.

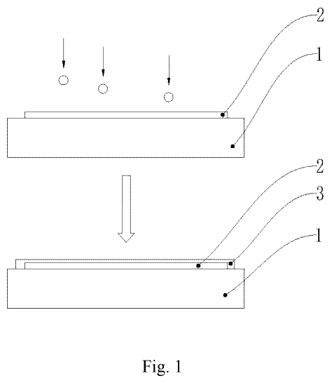

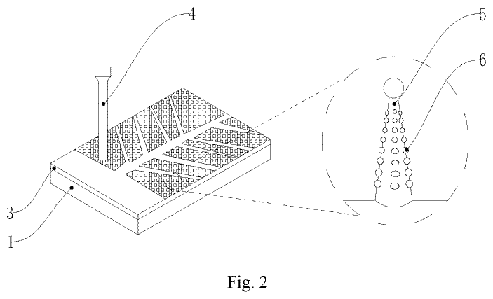

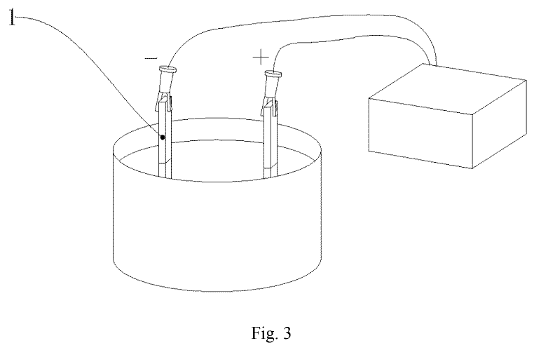

As shown in FIGS. 1-3, an embodiment of the present disclosure provides a method for fabricating a maskless dendritic silicon nanostructure array, including the following steps.

### Pretreatment

A copper layer 2 is deposited on a surface of a silicon substrate 1. The copper layer 2 is passivated to form an insulating passivation film 3.

### First Laser Induction

A first laser beam is applied to a surface of the insulating passivation film 3 for a first laser induction to remove the insulating passivation film 3 from a designated region and form a primary needle-shaped protrusion structure 5 within the designated region.

### Second Laser Induction

A second laser beam 4 is applied to a surface of the primary needle-shaped protrusion structure 5 for a second laser induction to form a secondary dome-shaped protrusion structure 6, such that a dual-level needle-shaped seed layer is formed on the surface of the silicon substrate.

### Electrodeposition

The dual-level needle-shaped seed layer is subjected to parameter-controlled electrodeposition to grow dendritic microstructures on the dual-level needle-shaped seed layer, so as to obtain a silicon wafer containing a maskless dendritic silicon nanostructure array.

Regarding the method provided herein, the first laser beam is applied to the surface of the insulating passivation film 3 for the first laser induction. After the first laser beam is applied, the primary needle-shaped protrusion structure 5 is formed within the designated region. Subsequently, the second laser beam 4 is applied to the surface of the primary needle-shaped protrusion structure 5 for the second laser induction, thereby generating the secondary dome-shaped protrusion structure 6 based on the primary needle-shaped protrusion structure 5. Then, copper is deposited on the secondary dome-shaped protrusion structure 6 through electrodeposition, so as to form a plurality of dendritic microstructures on the secondary dome-shaped protrusion structure 6.

The maskless dendritic silicon nanostructure array is composed of a plurality of dendritic silicon nanostructure units. Each dendritic silicon nanostructure unit includes a primary needle-shaped protrusion structure 5 and a plurality of secondary dome-shaped protrusion structures 6, with a plurality of dendritic microstructures further formed on each of the secondary dome-shaped protrusion structures 6. In practice, each secondary dome-shaped protrusion structure 6 further grows into a small tree, from which multiple dendritic branch microstructures are developed. The dendritic silicon nanostructure unit is dendritic in form, where the primary needle-shaped protrusion structure 5 serves as a main trunk, the secondary dome-shaped protrusion structures 6 serve as branches, and the dendritic microstructures formed on the secondary dome-shaped protrusion structures 6 serve as secondary branches.

The fabrication method involves a two-stage laser induction and a single electrodeposition process. The pattern of the maskless dendritic silicon nanostructure array is determined by a processing path of the first laser beam, without the need for a mask, thereby avoiding potential damage and contamination to the silicon nanostructure array caused by mask removal. Moreover, a maskless dendritic silicon nanostructure array with a designated pattern can be formed on the surface of the silicon wafer, achieving bionic patterning of microstructures on the surface of the silicon wafer. During the electrodeposition process, copper ions in the electrolyte solution migrate toward a surface of the dual-level needle-shaped seed layer, where the dual-level needle-shaped seed layer serves as a cathode. Since the dual-level needle-shaped seed layer is conductive, the copper ions gain electrons and are reduced to copper atoms, which are then deposited onto the dual-level needle-shaped seed layer. Additionally, dendritic microstructures develop branching during the deposition process, further increasing the specific surface area.

The silicon wafer fabricated by the aforementioned method exhibits microchannels formed between the dendritic silicon nanostructure units, enabling efficient capillary mass transfer along the microchannel walls. Meanwhile, since each dendritic silicon nanostructure unit includes a plurality of secondary dome-shaped protrusion structures 6 and dendritic microstructures, it possesses a substantially enlarged specific surface area, enabling efficient evaporative heat transfer along a direction perpendicular to the microchannels, thereby enhancing the heat transfer limit.

The passivation treatment may refer to existing procedures for forming a passivation film on copper, including the following steps. The surface of the copper layer 2 is polished. Oils and oxides on the surface of the copper layer 2 are removed by an acidic cleaning solution. The silicon substrate 1, including the copper layer 2, is immersed in a passivation solution, which may be benzotriazole (BTA) or a sodium silicate solution. By controlling the concentration, temperature and immersion time of the passivation solution, a thickness of the insulating passivation film 3 can be regulated.

In some embodiments, the first laser induction and the second laser induction are performed using an ultraviolet femtosecond laser direct-writing device.

The first laser beam and the second laser beam 4 emitted from the ultraviolet femtosecond laser direct-writing device are ultraviolet femtosecond lasers. A focal position of the first laser beam is determined using the ultraviolet femtosecond laser direct-writing device, such that, through sputtering and remelting mechanisms, an array of primary needle-shaped protrusion structures 5 with a designated pattern is formed on the insulating passivation film 3. Subsequently, a focal position of the second laser beam 4 is determined using the ultraviolet femtosecond laser direct-writing device, and the second laser beam 4 is irradiated onto the primary needle-shaped protrusion structures 5, such that, based on the primary needle-shaped protrusion structures, a plurality of secondary dome-shaped protrusion structures 6 are formed through sputtering and remelting mechanisms.

In some embodiments, the first laser beam has a pulse width of 80-100 fs and a wavelength of 300-400 nm.

The focal position of the first laser beam is located on a designated region of the insulating passivation film 3, such that the primary needle-shaped protrusion structure 5 is formed on the silicon surface. The primary needle-shaped protrusion structures 5 are combined to form an array. By controlling the path of the first laser beam, an array with a specific pattern of primary needle-shaped protrusion structures 5 can be generated. Subsequently, the second laser induction and electrodeposition are performed, complex dendritic structures are formed on the array of primary needle-shaped protrusion structures 5.

In some embodiments, the second laser beam 4 has a pulse width of 25-60 fs and a wavelength of 175-275 nm.

Similarly, the focal position of the second laser beam 4 is located on a designated region of the primary needle-shaped protrusion structures, such that the secondary dome-shaped protrusion structures 6 are formed on the primary needle-shaped protrusion structures. By adjusting the parameters of the second laser beam 4 on the ultraviolet femtosecond laser direct-writing device, the size of the secondary dome-shaped protrusion structures 6 can be controlled, thereby adjusting the size of the dendritic silicon nanostructure units.

In some embodiments, the primary needle-shaped protrusion structure 5 has a height of 2-6 μm, and the secondary dome-shaped protrusion structure 6 has a size of 200-600 nm.

The primary needle-shaped protrusion structures 5 are at the micrometer scale, whereas the secondary dome-shaped protrusion structures 6 are at the nanometer scale. The primary needle-shaped protrusion structures 5 serve to provide support and guide flow, while the secondary dome-shaped protrusion structures 6, together with the dendritic microstructures provided thereon, serve to increase the specific surface area, thereby enhancing heat transfer efficiency. The height of the primary needle-shaped protrusion structures 5 can be adjusted by controlling the pulse width and wavelength of the first laser beam, and the size of the secondary dome-shaped protrusion structures 6 can be adjusted by controlling the pulse width and wavelength of the second laser beam 4.

In some embodiments, an initial current density and a deposition time of the parameter-controlled electrodeposition satisfy the following function:

$$f ( t ) = Kt + b .$$

In the above formula, f(t) represents a real-time current density; K represents a current slope, and is 0.003-0.2 A/(cm²·s); t represents the deposition time, and is 30-200 s; and b represents the initial current density, and is 0.06-0.2 A/cm².

In the electrodeposition step, a variable-current electrodeposition method is employed. By regulating the magnitude of the current, a growth rate relationship between primary seed nuclei and secondary crystal branches can be adjusted, thereby forming a dendritic microstructure morphology. The longer the deposition time, the more branches the dendritic microstructures develop, resulting in a more complex dendritic microstructure.

Using the above function, a lower current density can be applied during an initial stage of deposition to induce initial nucleation on the secondary dome-shaped protrusion structures 6 and promote uniform upward growth of the copper microstructures. As time progresses, the current density is gradually increased to enable lateral growth of the copper microstructures, forming branches and extensions, ultimately producing a multi-level dendritic structure in the later stage of deposition. In the above formula, K represents the current slope, representing a ratio of current density to time, t represents the deposition time for the parameter-controlled electrodeposition, and b represents the initial current density.

In some embodiments, in the electrodeposition step, an electrolyte solution used in the parameter-controlled electrodeposition is prepared by mixing a CuSO₄ solution having a concentration of 0.4-0.8 M with a H₂SO₄ solution having a concentration of 0.5-0.9 M.

In the specific procedure, the silicon substrate 1 with the dual-level needle-shaped seed layer is connected to a negative electrode of a power supply to serve as the cathode, while a phosphor copper plate is connected to a positive electrode of the power supply to serve as an anode, maintaining the balance of copper ions in the electrolyte solution. The CuSO₄ solution primarily serves to provide copper ions, and its concentration affects a supply rate of copper ions, whereas the H₂SO₄ solution primarily serves to adjust the acidity of the solution.

In some embodiments, in the pretreatment step, the copper layer 2 is deposited on the surface of the silicon substrate by magnetron sputtering with pure copper as a target material, and the copper layer 2 has a thickness of 5-7 μm.

In some embodiment, a purity of the pure copper is 99.99%, and the copper layer 2 has the thickness of 5-7 μm. Copper of this purity contains minimal metallic impurities, thereby avoiding any influence of impurities on the absorption of the first laser beam and the second laser beam 4 during the first laser induction and second laser induction, as well as avoiding any impact of impurities on a growth rate of the copper during electrodeposition.

The thickness of the copper layer 2 affects the formation of the dual-level needle-shaped seed layer. The primary needle-shaped protrusion structures 5 are formed by melting the surface of the copper layer 2 with the energy of the first laser beam. If the copper layer 2 is too thick, it cannot provide sufficient copper to form the primary needle-shaped protrusion structures, and if the primary needle-shaped protrusion structures are too small, the secondary dome-shaped protrusion structures cannot be formed on them by using the second laser beam, ultimately affecting the formation of the dual-level needle-shaped seed layer. Conversely, if the copper layer 2 is too thin, an overall thickness of the silicon wafer is increased, and the copper in the copper layer 2 cannot be effectively utilized, resulting in material waste.

In an embodiment, a thickness of the insulating passivation film 3 is 0.5-2 μm. When the thickness of the insulating passivation film 3 is below 2 μm, incomplete vaporization of the insulating passivation film 3 during the first laser induction can be avoided, thereby preventing molten redeposition on the surface of the copper layer 2, which would otherwise affect the precision and quality of the subsequent electrodeposition process. When the thickness of the insulating passivation film 3 is above 0.5 μm, the insulating passivation film 3 is sufficiently thick to protect the copper layer 2.

The present disclosure further provides a silicon wafer, including a silicon nanostructure array. The silicon nanostructure array is obtained by the above-described method.

By adjusting the pulse width and wavelength of the first laser beam, the pulse width and wavelength of the second laser beam 4, and the current magnitude during electrodeposition, a bionic topology-optimized pattern distribution can be achieved, resulting in optimal heat and mass transfer performance. The dendritic silicon nanostructure units within the silicon nanostructure array are arranged in an orderly manner, thereby mitigating the issue of localized hotspots that arises in conventional chips from the random distribution of surface nanostructures.

### Example 1

Provided herein is a method for fabricating a maskless dendritic silicon nanostructure array, including the following steps.

A copper layer 2 having a thickness of 7 μm is deposited on a surface of a silicon substrate by magnetron sputtering. The copper layer 2 is passivated to form an insulating passivation film 3 having a thickness of 2 μm.

A first laser beam is emitted from an ultraviolet femtosecond laser direct-writing device. The first laser beam is applied to a surface of the insulating passivation film 3 for a first laser induction to remove the insulating passivation film 3 from a designated region and form a primary needle-shaped protrusion structure 5 within the designated region. The first laser beam has a pulse width of 80 fs and a wavelength of 300 nm.

A second laser beam 4 is emitted from the ultraviolet femtosecond laser direct-writing device. The second laser beam 4 is applied toa surface of the primary needle-shaped protrusion structure 5 for a second laser induction to form a secondary dome-shaped protrusion structure 6, thereby forming a dual-level needle-shaped seed layer on the surface of the silicon substrate. The second laser beam 4 has a pulse width of 25 fs and a wavelength of 175 nm.

The dual-level needle-shaped seed layer is subjected to parameter-controlled electrodeposition. An electrolyte solution used in the parameter-controlled electrodeposition is prepared by mixing a CuSO₄ solution having a concentration of 0.4 M with a H₂SO₄ solution having a concentration of 0.6 M.

An initial current density and a deposition time of the parameter-controlled electrodeposition satisfy the following function:

$$f ( t ) = Kt + b .$$

In the above function, f(t) represents a real-time current density; b represents the initial current density, and is 0.2 A/cm²; K represents a current slope, and is 0.05 A/(cm²·s); and t represents the deposition time, and is 30 s.

After the parameter-controlled electrodeposition, dendritic microstructures are grown on the dual-level needle-shaped seed layer, so as to obtain a silicon wafer containing the maskless dendritic silicon nanostructure array.

### Example 2

The steps of the method in Example 2 are substantially the same as those in Example 1, except that in the parameter-controlled electrodeposition, t is 60 s.

### Example 3

The steps of the method in Example 3 are substantially the same as those in Example 1, except that in the parameter-controlled electrodeposition, b is 0.06 A/cm², K is 0.003 A/(cm²·s), and t is 200 s.

### Example 4

The steps of the method in Example 4 are substantially the same as those in Example 1, except that in the parameter-controlled electrodeposition, b is 0.06 A/cm², K is 0.004 A/(cm²·s), and t is 200 s.

### Example 5

The steps of the method in Example 5 are substantially the same as those in Example 1, except that in the parameter-controlled electrodeposition, b is 0.06 A/cm², K is 0.005 A/(cm²·s), and t is 200 s.

### Example 6

The steps of the method in Example 6 are substantially the same as those in Example 1, except that the thickness of the copper layer 2 is 5 μm; the thickness of the insulating passivation film 3 is 0.5 μm; the first laser beam has the pulse width of 100 fs and the wavelength of 400 nm; the second laser beam 4 has the pulse width of 60 fs and the wavelength of 275 nm; the concentration of the CuSO₄ solution is 0.8 M, and the concentration of the H₂SO₄ solution is 0.9 M.

### Blank Control Group

The steps of the method in the blank control group are substantially the same as those in Example 1, except that in the parameter-controlled electrodeposition, t is 0 S.

The silicon wafers containing the maskless dendritic silicon nanostructure arrays obtained in Examples 1-5 and the blank control group are observed using a scanning electron microscopy (SEM).

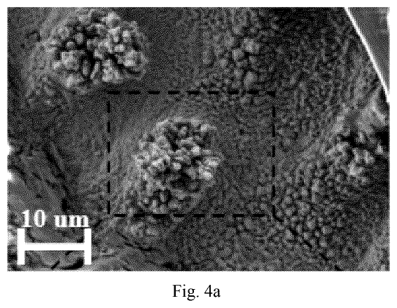

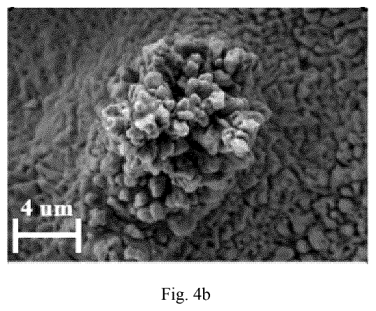

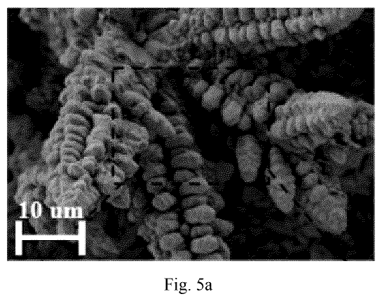

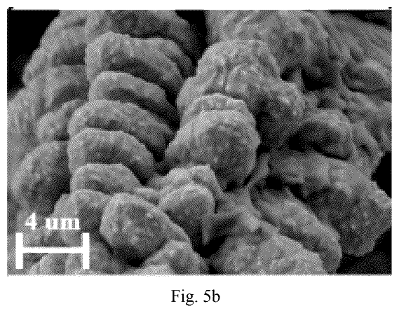

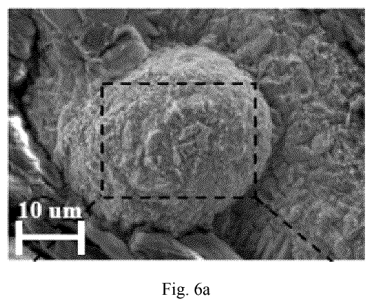

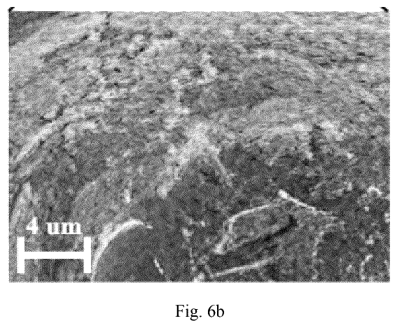

Referring to FIGS. 4a-4b, 5a-5b and 6a-6b, under the identical conditions except for varying deposition time, the growth of the dendritic microstructures demonstrates that the number of branches increases progressively with increasing deposition time t, indicating that the deposition time/directly influences the branching of the dendritic microstructures.

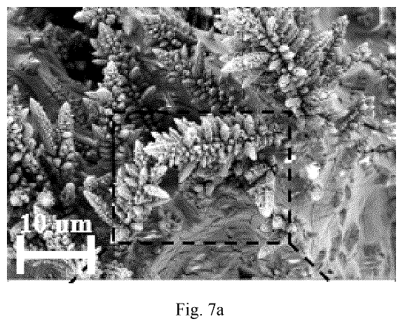

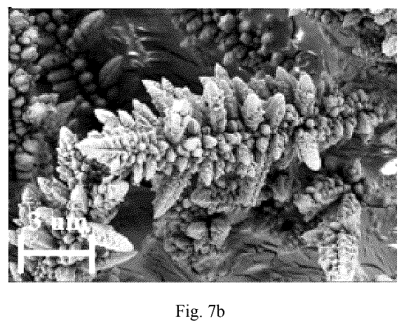

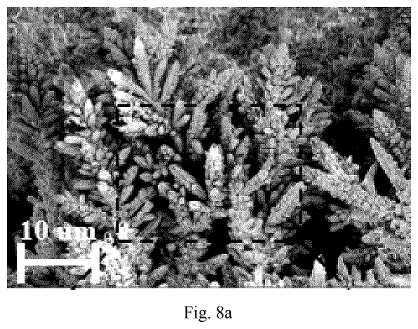

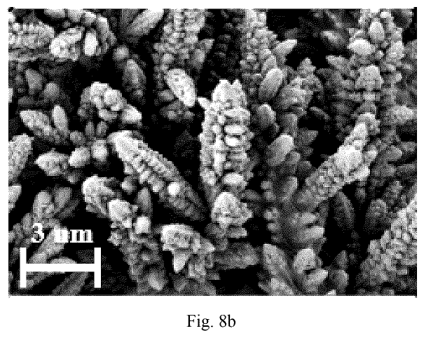

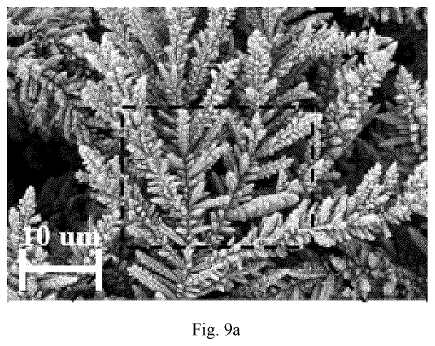

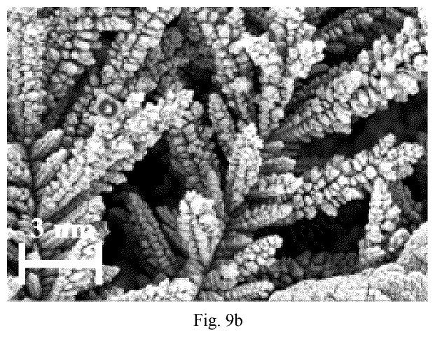

Referring to FIGS. 7a-7b, 8a-8b and 9a-9b, the growth morphology of the microstructures varies with different current slopes. When the current slope is 0.003 A/(cm²·s), the microstructure branches are relatively short and thick. When the current slope is 0.005 A/(cm²·s), the microstructure branches are relatively long. These results indicate that the current slope has a significant effect on the morphology of the dendritic microstructures.

It should be noted that the described embodiments are merely illustrative, and are not intended to limit the scope of the present disclosure. It should be understood that various modifications, changes and replacements made by those skilled in the art without departing from the spirit of the disclosure shall fall within the scope of the present disclosure defined by the appended claims.

What is claimed is:

1. A method for fabricating a maskless dendritic silicon nanostructure array, comprising:
depositing a copper layer on a surface of a silicon substrate, and passivating the copper layer to form an insulating passivation film;
applying a first laser beam to a surface of the insulating passivation film for a first laser induction to remove the insulating passivation film from a designated region and form a primary needle-shaped protrusion structure within the designated region;
applying a second laser beam to a surface of the primary needle-shaped protrusion structure for a second laser induction to form a secondary dome-shaped protrusion structure, such that a dual-level needle-shaped seed layer is formed on the surface of the silicon substrate; and
subjecting the dual-level needle-shaped seed layer to parameter-controlled electrodeposition to grow dendritic microstructures on the dual-level needle-shaped seed layer, so as to obtain a silicon wafer containing the maskless dendritic silicon nanostructure array;
wherein an initial current density and a deposition time of the parameter-controlled electrodeposition satisfy the following function:
$$f ( t ) = Kt + b ;$$
wherein f(t) represents a real-time current density; K represents a current slope, and is 0.003-0.2 A/(cm²·s); t represents the deposition time, and is 30-200 s; and b represents the initial current density, and is 0.06-0.2 A/cm².

2. The method of claim 1, wherein the first laser induction and the second laser induction are performed using an ultraviolet femtosecond laser direct-writing device.

3. The method of claim 1, wherein the first laser beam has a pulse width of 80-100 fs and a wavelength of 300-400 nm.

4. The method of claim 1, wherein the second laser beam has a pulse width of 25-60 fs and a wavelength of 175-275 nm.

5. The method of claim 1, wherein the primary needle-shaped protrusion structure has a height of 2-6 μm, and the secondary dome-shaped protrusion structure has a size of 200-600 nm.

6. The method of claim 1, wherein an electrolyte solution used in the parameter-controlled electrodeposition is prepared by mixing a CuSO₄ solution having a concentration of 0.4-0.8 M with a H₂SO₄ solution having a concentration of 0.5-0.9 M.

7. The method of claim 1, wherein the copper layer is deposited on the surface of the silicon substrate by magnetron sputtering with pure copper as a target material; and
the copper layer has a thickness of 5-7 μm.

8. The method of claim 1, wherein a thickness of the insulating passivation film is 0.5-2 μm.

9. A silicon wafer, comprising:
a silicon nanostructure array;
wherein the silicon nanostructure array is obtained by the method of claim 1.
